(19) United States
(12) Patent Application Publication
(10) Pub. No.: US 2009/0095992 A1
(43) Pub. Date: Apr. 16, 2009

(54) SEMICONDUCTOR DEVICE INCLUDING MOS FIELD EFFECT TRANSISTOR AND METHOD FOR MANUFACTURING THE SEMICONDUCTOR DEVICE

(76) Inventors: Tomoya SANUKI, Yokohama-shi (JP); Kazunobu Ohta, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/962,431

(22) Filed: Dec. 21, 2007

(30) Foreign Application Priority Data
Dec. 22, 2006 (JP) 2006-346494

(51) Int. Cl. H01L 27/088; H01L 21/336

(52) U.S. Cl. 257/288; 438/294; 257/E27.06; 257/E21.409

(57) ABSTRACT

Element isolation regions are formed in a semiconductor substrate of a first conductivity type. A gate insulator is formed on the semiconductor substrate between the element isolation regions. A gate electrode is formed on the gate insulator. Sidewall insulating films are formed on side surfaces of the gate electrode. Trenches are formed on the semiconductor substrate between the element isolation regions and the gate electrode. A first epitaxial semiconductor layer of a second conductivity type is formed by the epitaxial growth method in each of the trenches. The first epitaxial semiconductor layer has a facet. A silicide film is formed on the first epitaxial semiconductor layer. A semiconductor region of the second conductivity type is formed in the semiconductor substrate under the first epitaxial semiconductor layer.

### CROSS-REFERENCE TO RELATED APPLICATIONS

This application is based upon and claims the benefit of priority from prior Japanese Patent Application No. 2006-346494, filed Dec. 22, 2006, the entire contents of which are incorporated herein by reference.

### BACKGROUND OF THE INVENTION

1. Field of the Invention

The present invention relates to a semiconductor device constituted of a MOS field effect transistor having an epitaxial semiconductor layer in the source and drain region, and a method for manufacturing the semiconductor device.

2. Description of the Related Art

In recent years, in a MOS field effect transistor (hereinafter referred to as a MOS transistor), a method for forming a trench (recess) by etching a region for forming a source and drain of a silicon semiconductor substrate to form an epitaxial silicon germanium (SiGe) layer in the trench is proposed (see, for example, Jpn. Pat. Appln. KOKAI Publication No. 2006-60222). There are two reasons for using this technique.

One of the reasons is that the technique is used for the purpose of increasing the channel mobility of the MOS transistor by giving distortion to the channel region of the MOS transistor. Silicon germanium (SiGe) has a lattice constant larger than that of silicon, and can give stress to the channel region by the epitaxial SiGe layer. As a result, it is possible to give distortion to the channel region, and increase the channel mobility of the MOS transistor. This is particularly effective for a p-channel MOS transistor in which a hole is used as a carrier.

The second reason is that the technique is used for the purpose of lowering the resistance of the source/drain region to lower the parasitic resistance in the characteristics of a MOS transistor. By forming a SiGe layer doped with impurities in the etched trench on the silicon substrate by the epitaxial growth method, it is possible to lower the resistance of the source/drain region. This is particularly effective for a p-channel MOS transistor in which the SiGe layer can be doped with boron (B).

However, in the above-mentioned technique, the following problem is caused.

As described previously, the epitaxial SiGe layer is formed by subjecting SiGe to selectively epitaxial growth in a trench formed on a silicon substrate. Under an epitaxial growth condition of high selectivity, the epitaxial SiGe layer is formed only on the exposed surface of the silicon substrate. Thus, the epitaxial SiGe layer is not formed on the side surface of an element isolation region, and a facet is formed on the epitaxial SiGe layer on the element isolation region side. As a result, a gap is formed between the element isolation region and the epitaxial SiGe layer. If such a gap is formed, when a silicide film is formed on the epitaxial SiGe layer, a silicide film is also formed on the facet.

In this case, the epitaxial SiGe layer is doped with boron (B), and hence diffusion of boron is caused by heat, a junction to be formed between the source/drain region and the silicon substrate is formed at a position on the silicon substrate side of the interface between the epitaxial SiGe layer and the silicon substrate. As a result, it becomes necessary, when the silicide film is formed on the epitaxial SiGe layer and the facet, to sufficiently separate the silicide film and the junction from each other. When the junction is extended toward the silicon substrate side, the junction is brought closer to the channel region beneath the gate electrode. If the junction is made closer to the channel region, the short channel characteristic of the MOS transistor is degraded, and hence it is necessary to sufficiently separate the epitaxial SiGe layer of the source/drain region from the channel region.

The merit obtained by the technique of using a SiGe layer in the source/drain region described above is that the effect of increasing the channel mobility by making the SiGe layer close to the channel region is enhanced. Accordingly, it is difficult to make bringing the SiGe layer close to the channel region and increasing the distance between the salicide film and the junction compatible with each other, and a solution for the incompatibility has been required.

The present invention provides a semiconductor device including a MOS transistor having an epitaxial semiconductor layer formed in a source/drain region, in which a salicide film formed on an epitaxial semiconductor layer and a junction formed between the source/drain region and a semiconductor substrate can be separated from each other without separating the epitaxial semiconductor layer from the channel region.

### BRIEF SUMMARY OF THE INVENTION

A semiconductor device according to a first aspect of the present invention comprises: element isolation regions formed in a semiconductor substrate of a first conductivity type; a gate insulator formed on the semiconductor substrate between the element isolation regions; a gate electrode formed on the gate insulator; sidewall insulating films formed on side surfaces of the gate electrode; a first epitaxial semiconductor layer of a second conductivity type formed by the epitaxial growth method in each of trenches formed on the semiconductor substrate between the element isolation regions and the gate electrode, the first epitaxial semiconductor layer having a facet; a silicide film formed on the first epitaxial semiconductor layer; and a semiconductor region of the second conductivity type formed in the semiconductor substrate under the first epitaxial semiconductor layer.

A semiconductor device according to a second aspect of the present invention comprises: element isolation regions formed in a semiconductor substrate of a first conductivity type; a gate insulator formed on the semiconductor substrate between the element isolation regions; a gate electrode formed on the gate insulator; sidewall insulating films formed on side surfaces of the gate electrode; a first epitaxial semiconductor layer of a second conductivity type formed by the epitaxial growth method in each of trenches formed on the semiconductor substrate between the element isolation regions and the gate electrode, the first epitaxial semiconductor layer having a facet; a second epitaxial semiconductor layer formed on the first epitaxial semiconductor layer by an epitaxial growth method; and a silicide film formed on the second epitaxial semiconductor layer.

A method of manufacturing a semiconductor device according to a third aspect of the present invention comprises: forming element isolation regions in a semiconductor substrate of a first conductivity type; forming a gate insulator on the semiconductor substrate between the element isolation regions; forming a gate electrode on the gate insulator; forming sidewall insulating films on side surfaces of the gate electrode; forming trenches on the semiconductor substrate between the element isolation regions and the gate electrode; introducing impurities of a second conductivity type into the semiconductor substrate under each of the trenches by ion implantation to form a semiconductor region of the second conductivity type; forming a first epitaxial semiconductor layer of the second conductivity type in each of the trenches, the first epitaxial semiconductor layer having a facet; and forming a silicide film on the first epitaxial semiconductor layer.

### BRIEF DESCRIPTION OF THE SEVERAL VIEWS OF THE DRAWING

FIG. 1 is a cross-sectional view showing a structure of a pMOS transistor of a first embodiment of the present invention.

FIG. 2 is a cross-sectional view of a step showing a manufacturing method of the pMOS transistor of the first embodiment.

FIG. 3 is a cross-sectional view of a step showing the manufacturing method of the pMOS transistor of the first embodiment.

FIG. 4 is a cross-sectional view of a step showing the manufacturing method of the pMOS transistor of the first embodiment.

FIG. 5 is a cross-sectional view of a step showing the manufacturing method of the pMOS transistor of the first embodiment.

FIG. 6 is a cross-sectional view of a step showing the manufacturing method of the pMOS transistor of the first embodiment.

FIG. 7 is a cross-sectional view of a step showing the manufacturing method of the pMOS transistor of the first embodiment.

FIG. 8 is a cross-sectional view showing a structure of a pMOS transistor of a second embodiment of the present invention.

FIG. 9 is a cross-sectional view of a step showing a manufacturing method of the PMOS transistor of the second embodiment.

FIG. 10 is a cross-sectional view of a step showing the manufacturing method of the pMOS transistor of the second embodiment.

FIG. 11 is a cross-sectional view showing a structure of a pMOS transistor of a third embodiment of the present invention.

FIG. 12 is a cross-sectional view of a step showing a manufacturing method of the pMOS transistor of the third embodiment.

FIG. 13 is a cross-sectional view of a step showing the manufacturing method of the pMOS transistor of the third embodiment.

### DETAILED DESCRIPTION OF THE INVENTION

A semiconductor device having a MOS transistor of each embodiment of the present invention will be described below with reference to the accompanying drawings. In the description, parts which are common throughout all the drawings are denoted by common reference symbols. Here, although a p-channel MOS field effect transistor (hereinafter referred to as a pMOS transistor) is taken as an example for description, the description can be applied to an n-channel MOS field effect transistor (hereinafter referred to as an nMOS transistor) by changing the conductivity type.

### FIRST EMBODIMENT

First, a pMOS transistor of a first embodiment of the present invention will be described.

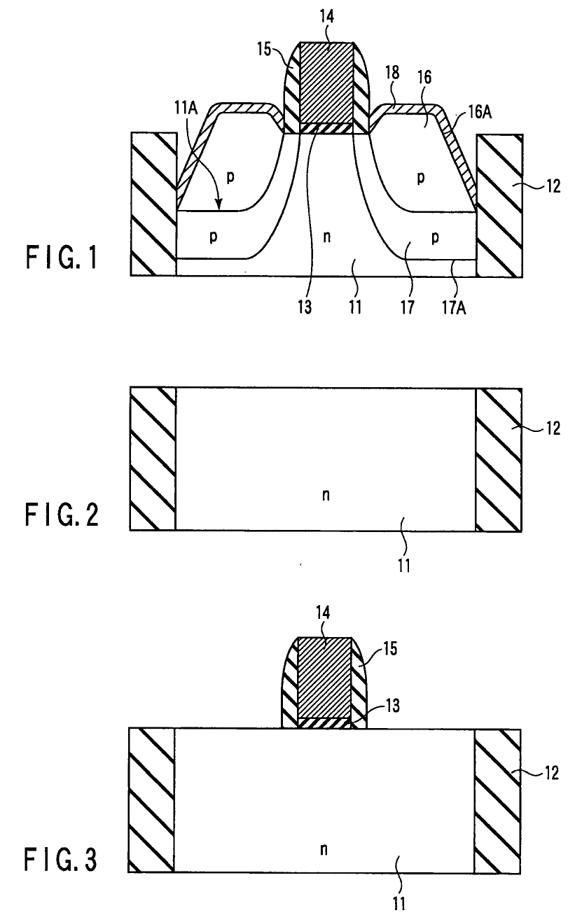

FIG. 1 is a cross-sectional view showing a structure of the pMOS transistor of the first embodiment.

In an n-type silicon semiconductor substrate or an n-type well region 11 (hereinafter referred to as a silicon substrate 11), element isolation regions 12 and an element region surrounded by the element isolation regions 12 are formed. The element region is a region in which an element (pMOS transistor in this case) is formed, and is electrically insulated and isolated by the element isolation regions 12. A gate insulator 13 is formed on the silicon substrate 11 interposed between the element isolation regions 12, and a gate electrode 14 is formed on the gate insulator 13. Further, sidewall spacers (sidewall insulating films) 15 are formed on the side surfaces of the gate electrode 14.

Trenches (recesses) 11A are formed on the silicon substrate 11 on both sides of the gate electrode 14, i.e., on the silicon substrate 11 between the element isolation regions 12 and the gate electrode 14, and p-type epitaxial semiconductor layers, e.g., epitaxial SiGe layers 16 into which, for example, p-type impurities are introduced are formed in the trenches 11A. The epitaxial SiGe layers 16 are arranged in such a manner that that a channel region formed in the silicon substrate 11 under the gate electrode 14 is interposed between the layers 16, thereby constituting a source/drain region.

The epitaxial SiGe layer 16 is formed by subjecting SiGe to selectively epitaxial growth in the trenches 11A formed on the silicon substrate 11. Therefore, as shown in FIG. 1, the epitaxial SiGe layer 16 is not formed on the side surface of each of the element isolation regions 12, and a facet 16A is formed on the part of each epitaxial SiGe layer 16 on the element isolation region 12 side. As a result, a gap is formed between each element isolation region 12 and each epitaxial SiGe layer 16.

A p-type semiconductor region 17 is formed in the silicon substrate 11 under each epitaxial SiGe layer 16. More specifically, a p-type semiconductor region 17 is formed in the silicon substrate 11 under the bottom and side surface of each trench 11A. In each p-type semiconductor region 17, the region formed under the trench bottom is formed deeper from the silicon substrate surface than the region formed in the vicinity of the channel region under the gate electrode on the side surface side of the trench. That is, a junction 17A formed between the p-type semiconductor region 17 and the n-type silicon substrate 11 is deep under the trench bottom, and is shallower than the part thereof under the trench bottom on the trench side surface side, i.e., in the vicinity of the channel region. Further, a silicide film (salicide film) 18 is formed on each epitaxial SiGe layer 16 and each facet 16A.

In a pMOS transistor having the structure shown in FIG. 1, a p-type diffusion layer 17B is formed in the silicon substrate 11 under each epitaxial SiGe layer 16 constituting the source/drain region by ion implantation of impurities, whereby the junction 17A under each trench bottom can be formed in a region deeper from the silicon substrate surface. As a result of this, the junction 17A can be sufficiently separated from the silicide film 18 without degrading the short channel characteristic of the transistor. Incidentally, in the ion implantation step for forming the p-type diffusion layer 17B, impurities are not introduced into the vicinity of the channel region (or the silicon substrate 11 under the sidewall spacer 15) under the gate electrode, and hence the junction 17A can be prevented from being brought close to the channel region.

Further, at this time, it is not necessary to separate the epitaxial SiGe layer 16 constituting the source/drain region from the channel region, and hence it is possible to apply sufficient stress to the channel region to give distortion thereto, and increase the channel mobility.

Incidentally, although an epitaxial SiGe layer is formed in this case as the epitaxial semiconductor layer, in the case of an nMOS transistor, it is sufficient if an epitaxial silicon carbide (SiC) layer is formed as the epitaxial semiconductor layer.

A manufacturing method of the pMOS transistor of the first embodiment will be described below.

FIGS. 2 to 7 are cross-sectional views each showing the manufacturing method of the PMOS transistor of the first embodiment.

First, trenches are formed in the silicon substrate 11 by the reactive ion etching (RIE) method, and the trenches are filled with insulating films, thereby forming element isolation regions 12 as shown in FIG. 2.

Then, an insulating film which becomes a gate insulator, for example, a silicon dioxide film on the silicon substrate 11, and a conducting film which becomes a gate electrode, for example, a polysilicon film is further formed on the silicon dioxide film. Subsequently, the silicon dioxide film and polysilicon film are processed by the RIE method or the like, and a gate insulator 13 and a gate electrode 14 are formed as shown in FIG. 3. Further, an insulating film, such as a silicon dioxide film and a silicon nitride film is deposited on the silicon substrate 11 and the gate electrode 14. Subsequently, the deposited insulating film is removed by the RIE method, and sidewall spacers 15 are formed on the side surfaces of the gate electrode 14 as shown in FIG. 3.

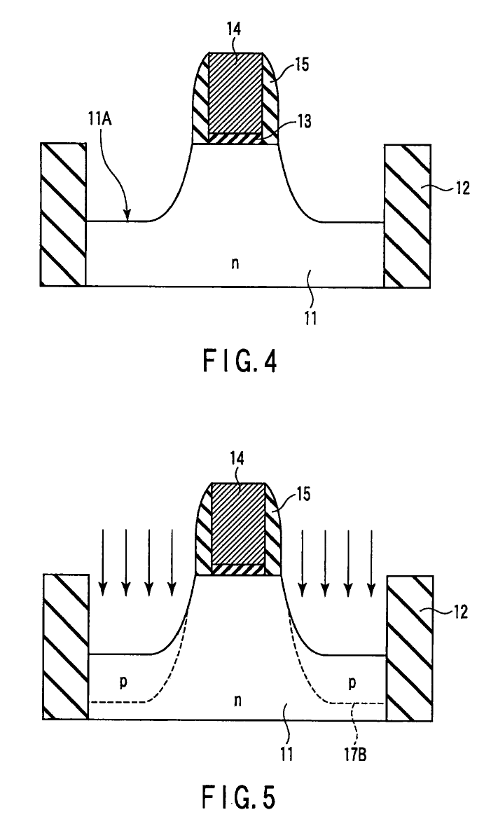

Then, the silicon substrate 11 on both sides of the gate electrode 14 which is the source/drain region, i.e., the silicon substrate 11 between each of the element isolation regions 12 and the gate electrode 14 is removed by the RIE method, and trenches (recesses) 11A are formed as shown in FIG. 4.

Subsequently, as shown in FIG. 5, the silicon substrate 11 under the trenches 11A is implanted with p-type impurities by the ion implantation method, thereby forming p-type semiconductor regions (p-type diffusion layers) 17B. At this time, in the case of the pMOS transistor, the substrate 11 is implanted with p-type impurities as described previously, the impurity type is, for example, boron (B), and the dose amount is 1.0×10¹² to 1.0×10¹⁶ cm⁻².

Further, in the case of an nMOS transistor, the silicon substrate is implanted with n-type impurities, the impurity type is, for example, phosphorus (P) or arsenic (As), and the dose amount is 1.0×10¹² to 1.0×10¹⁶ cm⁻².

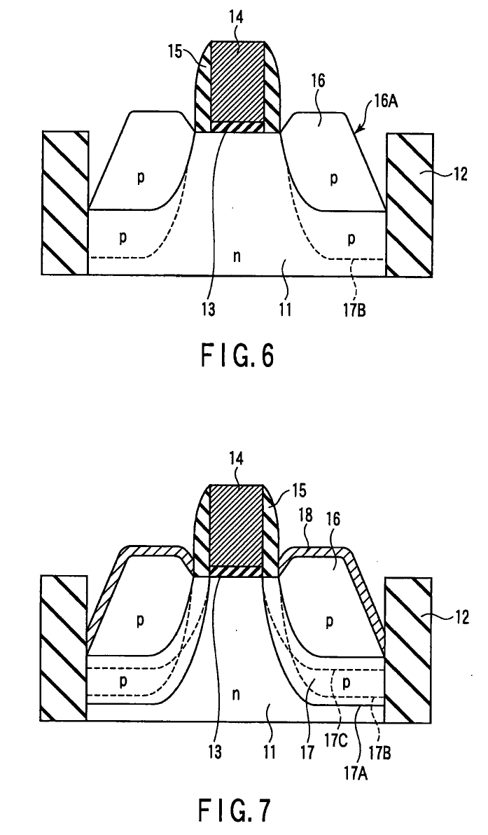

Then, a p-type epitaxial semiconductor layer, for example, a p-type epitaxial SiGe layer 16 is formed in each of the trenches 11A formed in the silicon substrate 11 by the selectively epitaxial growth method as shown in FIG. 6. At this time, the epitaxial SiGe layer 16 is formed by subjecting SiGe to selectively epitaxial growth in the trench 11A. Under an epitaxial growth condition of high selectivity, the epitaxial SiGe layer 16 is formed only on the exposed surface of the silicon substrate in the trench 11A. Thus, the epitaxial SiGe layer 16 is not formed on the side surface of the element isolation region 12, and a facet 16A is formed on the part of the epitaxial SiGe layer 16 on the element isolation region 12 side. As a result, a gap is formed between the element isolation region 12 and the epitaxial SiGe layer 16.

After the epitaxial SiGe layer 16 is formed, a heating step is performed, whereby the p-type impurities introduced into the epitaxial SiGe layer 16 are thermally diffused. Hence, a p-type diffusion layer 17C is formed in the silicon substrate 11 on the outer side of the epitaxial SiGe layer 16 as shown in FIG. 7. Here, as described previously, in the case of the pMOS transistor, p-type impurities are introduced into the epitaxial SiGe layer 16, the impurity type is, for example boron (B), and the impurity concentration is 1.0×10¹⁸ to 1.0×10²⁰ cm⁻³. Further, in the case of the nMOS transistor, an n-type epitaxial semiconductor layer, for example, n-type epitaxial SiC is formed. In this case, n-type impurities are introduced into the epitaxial SiC layer, the impurity type is, for example, phosphorus (P) or arsenic (As), and the impurity concentration is 1.0×10¹⁸ to 1.0×10²⁰ cm⁻³.

Furthermore, on the structure shown in FIG. 6, i.e., on the epitaxial SiGe layer 16, a film of a high-melting point metal, such as nickel (Ni), tungsten (W), titanium (Ti), cobalt (Co), and the like is deposited. Subsequently, heat treatment is performed to make the epitaxial SiGe layer and the high-melting point metal film react with each other, thereby turning the high-melting point metal film into a silicide. Thereafter, the unreacted part of the high-melting point metal film is removed, and a silicide film 18 is left on the epitaxial SiGe layer 16 as shown in FIG. 7. As a result, a silicide film (salicide film) 18 is formed on the exposed surfaces of the epitaxial SiGe layer 16 and the facet 16A in a self-aligning manner. Incidentally, in this embodiment, although the silicide film is formed only on the epitaxial SiGe layer 16 constituting the source/drain region, the silicide film may be formed also on the gate electrode 14 by using the similar step.

Here, as shown in FIG. 7, the p-type diffusion layer 17C formed by the diffusion of the p-type impurities from the p-type diffusion layer 17B formed by the ion implantation method and the epitaxial SiGe layer 16 has the same polarity (conductivity type) of the p-type, and hence the junction 17A is formed in the silicon substrate 11 on the outer side of the p-type diffusion layer 17B when viewed from the epitaxial SiGe layer 16. As a result of the above, the pMOS transistor of the first embodiment shown in FIG. 1 is manufactured.

As described above, according to the first embodiment, in a semiconductor device including a MOS transistor in which an epitaxial semiconductor layer is formed in a source/drain region, a salicide film formed on the epitaxial semiconductor layer and a junction formed between the source/drain region and the semiconductor substrate can be separated from each other without separating the epitaxial semiconductor layer from the channel region. Further, it is possible to apply sufficient stress to the channel region to give distortion thereto, and lower the resistance of the source/drain region to reduce the parasitic resistance.

### SECOND EMBODIMENT

Next, a pMOS transistor of a second embodiment of the present invention will be described. The same parts as the corresponding parts in the first embodiment are denoted by the same reference symbols. In the first embodiment, although a silicide film is formed on the epitaxial SiGe layer, in the second embodiment, a silicon layer is formed on the epitaxial SiGe layer, and a silicide film is formed on the silicon layer.

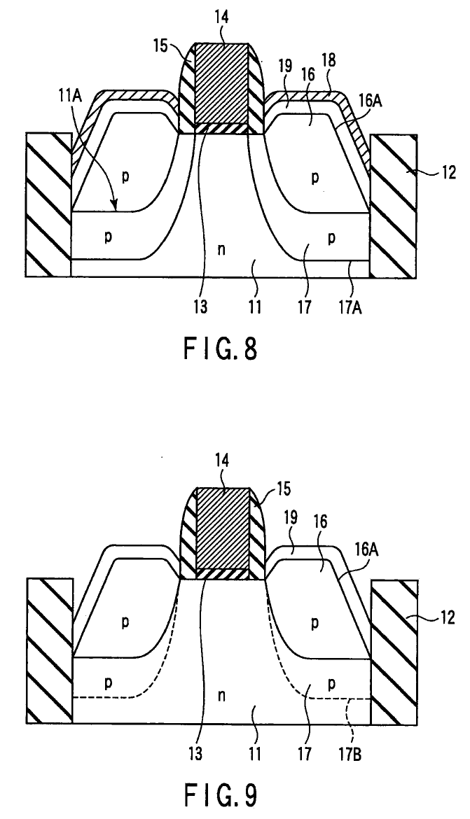

FIG. 8 is a cross-sectional view showing the structure of the pMOS transistor of the second embodiment.

Element isolation regions 12 and an element region surrounded by the element isolation regions 12 are formed on a silicon substrate 11. A gate insulator 13 is formed on the silicon substrate 11 interposed between the element isolation regions 12, and a gate electrode 14 is formed on the gate insulator 13. Further, sidewall spacers (sidewall insulating films) 15 are formed on the side surfaces of the gate electrode 14.

Trenches (recesses) 11A are formed on the silicon substrate 11 on both sides of the gate electrode 14, i.e., on the silicon substrate 11 between the element isolation regions 12 and the gate electrode 14, and p-type epitaxial semiconductor layers, e.g., epitaxial SiGe layers 16 into which, for example, p-type impurities are introduced are formed in the trenches 11A. The epitaxial SiGe layers 16 are arranged in such a manner that a channel region formed in the silicon substrate 11 under the gate electrode 14 is interposed between the layers 16, thereby constituting a source/drain region.

The epitaxial SiGe layer 16 is formed by subjecting SiGe to selectively epitaxial growth in the trenches 11A formed on the silicon substrate 11, and hence, as shown in FIG. 8, a facet 16A is formed on the part of each epitaxial SiGe layer 16 on the element isolation region 12 side.

A p-type semiconductor region 17 is formed in the silicon substrate 11 under each epitaxial SiGe layer 16. A junction 17A formed between the p-type semiconductor region 17 and the n-type silicon substrate 11 is deep under the trench bottom, and is shallower than the part thereof under the trench bottom on the trench side surface side, i.e., in the vicinity of the channel region.

An epitaxial semiconductor layer, for example, an epitaxial silicon (Si) layer 19 is formed on the epitaxial SiGe layer 16 and the facet 16A. The epitaxial Si layer 19 is formed on the epitaxial SiGe layer 16 and the facet 16A by epitaxially growing Si. At this time, Si is also grown on the surface of the facet 16A, and the epitaxial Si layer 19 is formed such that a facet does not appear on the layer 19.

Further, a silicide film (salicide film) 18 is formed on the epitaxial Si layer 19.

In the pMOS transistor having the structure shown in FIG. 8, a p-type diffusion layer 17B is formed in the silicon substrate 11 under the epitaxial SiGe layer 16 constituting the source/drain region by ion implantation of impurities, whereby it is possible to form the junction 17A beneath the trench bottom at a region deeper than the silicon substrate surface without bringing the junction 17A under the gate electrode close to the channel region. As a result of this, the junction 17A can be sufficiently separated from the silicide film 18 without degrading the short channel characteristic of the transistor. Incidentally, in the ion implantation step for forming the p-type diffusion layer 17B, impurities are not introduced into the vicinity of the channel region under the gate electrode, and hence the junction 17A can be prevented from being brought close to the channel region.

Further, at this time, it is not necessary to separate the epitaxial SiGe layer 16 constituting the source/drain region from the channel region, and hence it is possible to apply sufficient stress to the channel region to give distortion thereto, and increase the channel mobility.

Further, the epitaxial Si layer 19 is formed on the epitaxial SiGe layer 16, and the silicide film is formed on the epitaxial Si layer 19. As a result, it is possible to further increase the distance between the silicide film 18 and the junction 17A. Furthermore, uniformity of the silicide film can be improved, and hence the junction leak is not increased.

Incidentally, in this embodiment, although an epitaxial SiGe layer is formed as the epitaxial semiconductor layer, it is advisable, in the case of the nMOS transistor, to form an epitaxial SiC layer as the epitaxial semiconductor layer.

A method of manufacturing the pMOS transistor of the second embodiment will be described below.

FIGS. 2 to 6, 9, and 10 are cross-sectional views of steps showing the method of manufacturing the pMOS transistor of the second embodiment.

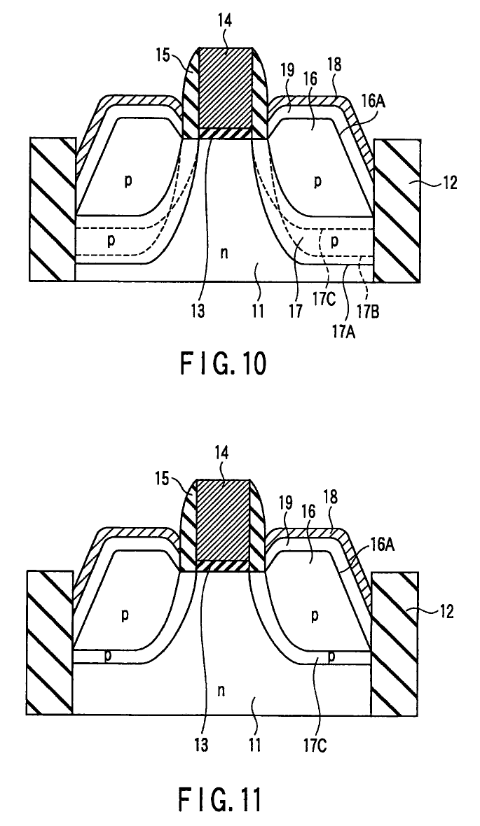

The steps shown in FIGS. 2 to 6 are the same as those of the manufacturing method in the first embodiment. As shown in FIG. 6, a p-type epitaxial SiGe layer 16 is formed in each of the trenches 11A formed on the silicon substrate 11 by the selectively epitaxial growth method. At this time, a facet 16A is formed on the part of each epitaxial SiGe layer 16 on the element isolation region 12 side. Thereafter, as shown in FIG. 9, an epitaxial Si layer is formed on the epitaxial SiGe layer 16 and the facet 16A. At this time, by epitaxially growing Si, the epitaxial Si layer 19 is formed on the epitaxial SiGe layer 16 and the facet 16A. That is, Si is also grown on the surface of the facet 16A, and the epitaxial Si layer 19 formed such that a facet does not appear on the layer 19. A thickness of the epitaxial Si layer 19 is, for example, 5 to 50 nm, and impurities may be introduced into the epitaxial Si layer 19 as in the case of the epitaxial SiGe layer 16.

Furthermore, on the structure shown in FIG. 9, i.e., on the epitaxial Si layer 19, a film of a high-melting point metal, such as nickel (Ni), tungsten (W), titanium (Ti), cobalt (Co), and the like is deposited. Subsequently, heat treatment is performed to make the epitaxial Si layer 19 and the high-melting point metal film react with each other, thereby turning the high-melting point metal film into a silicide. Thereafter, the unreacted part of the high-melting point metal film is removed, and a silicide film 18 is left on the epitaxial Si layer 19 as shown in FIG. 10. As a result, a silicide film (salicide film) 18 is formed on the exposed surface of the epitaxial Si layer 19 in a self-aligning manner. Incidentally, in this embodiment, although the silicide film is formed only on the epitaxial Si layer 19 constituting the source/drain region, the silicide film may be formed also on the gate electrode 14 by using the similar step.

After the epitaxial SiGe layer 16 is formed, a heating step is performed, whereby the p-type impurities introduced into the epitaxial SiGe layer 16 are thermally diffused. Hence, a p-type diffusion layer 17C is formed in the silicon substrate 11 on the outer side of the epitaxial SiGe layer 16. As shown in FIG. 10, the p-type diffusion layer 17C formed by the diffusion of the p-type impurities from the p-type diffusion layer 17B formed by the ion implantation method and the epitaxial SiGe layer 16 has the same polarity (conductivity type) as the p-type, and hence the junction 17A is formed in the silicon substrate 11 on the outer side of the p-type diffusion layer 17B when viewed from the epitaxial SiGe layer 16. As a result of the above, the pMOS transistor of the second embodiment shown in FIG. 8 is manufactured.

As described above, according to the second embodiment, in a semiconductor device including a MOS transistor in which an epitaxial semiconductor layer is formed in the source/drain region, a salicide film formed on the epitaxial semiconductor layer and a junction formed between the source/drain region and the semiconductor substrate can be separated from each other without separating the epitaxial semiconductor layer from the channel region. Further, it is possible to apply sufficient stress to the channel region to give distortion thereto, and lower the resistance of the source/drain region to reduce the parasitic resistance. The other configurations and advantages are the same as those of the first embodiment.

### THIRD EMBODIMENT

Next, a pMOS transistor of a third embodiment of the present invention will be described. The same parts as the corresponding parts in the second embodiment are denoted by the same reference symbols. In the second embodiment, although a p-type diffusion layer 17B is formed in the silicon substrate 11 under the epitaxial SiGe layer 16 by the ion implantation method, thereby constituting the p-type semiconductor region 17. However, in the third embodiment, a p-type diffusion layer 17B is not formed by the ion implantation method, and only a p-type diffusion layer 17C is formed by the thermal diffusion of the p-type impurities from the epitaxial SiGe layer 16.

FIG. 11 is a cross-sectional view showing the structure of the pMOS transistor of the third embodiment.

Element isolation regions 12 and an element region surrounded by the element isolation regions 12 are formed on a silicon substrate 11. A gate insulator 13 is formed on the silicon substrate 11 interposed between the element isolation regions 12, and a gate electrode 14 is formed on the gate insulator 13. Further, sidewall spacers (sidewall insulating films) 15 are formed on the side surfaces of the gate electrode 14.

Trenches (recesses) 11A are formed on the silicon substrate 11 on both sides of the gate electrode 14, i.e., on the silicon substrate 11 between the element isolation regions 12 and the gate electrode 14, and p-type epitaxial semiconductor layers, e.g., p-type epitaxial SiGe layers 16 are formed in the trenches 11A. The epitaxial SiGe layers 16 are arranged in such a manner that a channel region formed in the silicon substrate 11 under the gate electrode 14 is interposed between the layers 16, thereby constituting a source/drain region.

The epitaxial SiGe layer 16 is formed by subjecting SiGe to selectively epitaxial growth in the trenches 11A formed on the silicon substrate 11, and hence, as shown in FIG. 8, a facet 16A is formed on the part of each epitaxial SiGe layer 16 on the element isolation region 12 side.

An epitaxial semiconductor layer, for example, an epitaxial Si layer 19 is formed on the epitaxial SiGe layer 16 and the facet 16A. The epitaxial Si layer 19 is formed on the epitaxial SiGe layer 16 and the facet 16A by epitaxially growing Si. At this time, Si is also grown on the surface of the facet 16A, and the epitaxial Si layer 19 is formed such that a facet does not appear on the layer 19.

Further, a silicide film (salicide film) 18 is formed on the epitaxial Si layer 19.

In the pMOS transistor having the structure shown in FIG. 11, the epitaxial Si layer 19 is formed on the epitaxial SiGe layer 16, and the silicide film is formed on the epitaxial Si layer 19. As a result, it is possible to further increase the distance between the silicide film 18 and the junction 17A. That is, the silicide film 18 and the junction 17A can be sufficiently separated from each other. Furthermore, uniformity of the slicide film can be improved, and hence the junction leak is not increased.

Incidentally, in this embodiment, although an epitaxial SiGe layer is formed as the epitaxial semiconductor layer, it is advisable, in the case of the nMOS transistor, to form an epitaxial SiC layer as the epitaxial semiconductor layer.

A method of manufacturing the pMOS transistor of the third embodiment will be described below.

FIGS. 2 to 4, 12, and 13 are cross-sectional views of steps showing the method of manufacturing the pMOS transistor of the third embodiment.

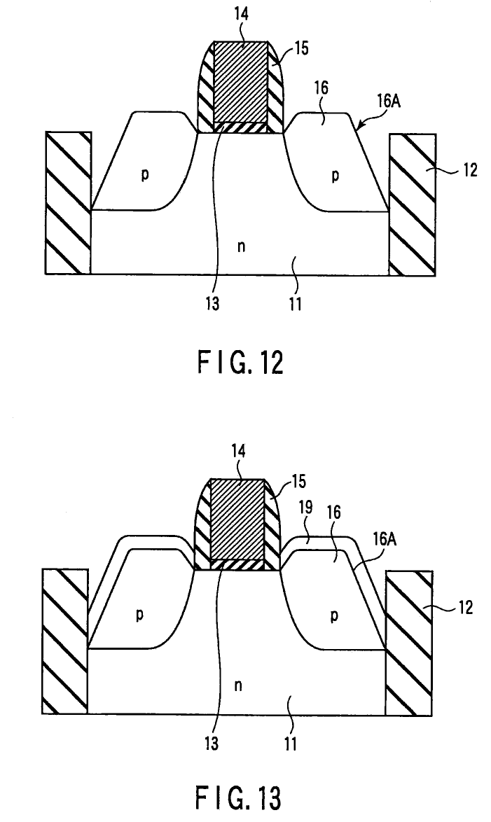

The steps shown in FIGS. 2 to 4 are the same as those of the manufacturing method in the first embodiment. As shown in FIG. 4, trenches (recesses) 11A are formed on the silicon substrate 11 on both sides of the gate electrode 14 in the source/drain region. Thereafter, as shown in FIG. 12, a p-type epitaxial SiGe layer 16 is formed in each trench 11A formed on the silicon substrate 11 by the selectively epitaxial growth method. At this time, a facet 16A is formed on the part of each epitaxial SiGe layer 16 on the element isolation region side.

Then, as shown in FIG. 13, an epitaxial Si layer 19 is formed on each epitaxial SiGe layer and facet 16A. At this time, Si is also grown on the surface of the facet 16A, and the epitaxial Si layer 19 is formed such that a facet does not appear on the layer 19.

Further, as shown in FIG. 11, a silicide film (salicide film) 18 is formed on each epitaxial Si layer 19 in a self-aligning manner. Incidentally, in this embodiment, although an example in which a silicide film is formed only on the epitaxial Si layer 19 constituting the source/drain region is shown, the silicide film may be formed also on the gate electrode 14 by using the similar step.

After the epitaxial SiGe layer 16 is formed, a heating step is performed, whereby the p-type impurities introduced into the epitaxial SiGe layer 16 are thermally diffused. Hence, a p-type diffusion layer 17C is formed in the silicon substrate 11 on the outer side of the epitaxial SiGe layer 16. As a result of the above, the pMOS transistor of the third embodiment shown in FIG. 11 is manufactured.

As described above, according to the third embodiment, in a semiconductor device including a MOS transistor having an epitaxial semiconductor layer formed in a source/drain region, a salicide film formed on an epitaxial semiconductor layer and a junction formed between the source/drain region and a semiconductor substrate can be separated from each other without separating the epitaxial semiconductor layer from the channel region. Further, it is possible to apply sufficient stress to the channel region to give distortion thereto, and lower the resistance of the source/drain region to reduce the parasitic resistance. The other configurations and advantages are the same as those of the second embodiment.

According to the embodiments of the present invention, it is possible to provide a semiconductor device including a MOS transistor having an epitaxial semiconductor layer formed in a source/drain region, in which a salicide film formed on an epitaxial semiconductor layer and a junction formed between the source/drain region and a semiconductor substrate can be separated from each other without separating the epitaxial semiconductor layer from the channel region.

Furthermore, each of the above-mentioned embodiments can not only be implemented singly, but can also be appropriately implemented in combination with other embodiments. Moreover, in each of the above-mentioned embodiments, inventions of various stages are included, and by appropriately combining a plurality of constituent elements disclosed in the embodiments with each other, inventions of various stages can be extracted.

What is claimed is:

1. A semiconductor device comprising:
element isolation regions formed in a semiconductor substrate of a first conductivity type;
a gate insulator formed on the semiconductor substrate between the element isolation regions;
a gate electrode formed on the gate insulator;
sidewall insulating films formed on side surfaces of the gate electrode;
a first epitaxial semiconductor layer of a second conductivity type formed by the epitaxial growth method in each of trenches formed on the semiconductor substrate between the element isolation regions and the gate electrode, the first epitaxial semiconductor layer having a facet;
a silicide film formed on the first epitaxial semiconductor layer; and
a semiconductor region of the second conductivity type formed in the semiconductor substrate under the first epitaxial semiconductor layer.

2. The semiconductor device according to claim 1, wherein
the semiconductor region is arranged between the semiconductor substrate of the first conductivity type and the first epitaxial semiconductor layer.

3. The semiconductor device according to claim 1, wherein
the first epitaxial semiconductor layers are formed in such a manner that a part of the semiconductor substrate under the gate electrode is interposed between the first epitaxial semiconductor layers, and constitute a source region and a drain region.

4. The semiconductor device according to claim 1, wherein
the facet is formed on a part of the first epitaxial semiconductor layer on the element isolation region side.

5. The semiconductor device according to claim 1, wherein
the semiconductor region is formed by introducing impurities of the second conductivity type thereinto by ion implantation.

6. The semiconductor device according to claim 5, wherein
the impurities are not introduced into a part of the semiconductor substrate under each sidewall insulating film by the ion implantation for forming the semiconductor region.

7. The semiconductor device according to claim 1, wherein
the first epitaxial semiconductor layer includes any one of a silicon germanium layer and a silicon carbide layer.

8. The semiconductor device according to claim 7, wherein
when the first epitaxial semiconductor layer includes the silicon germanium layer, p-type impurities are introduced into the silicon germanium layer, and p-type impurities are implanted into the semiconductor region by an ion implantation method.

9. The semiconductor device according to claim 7, wherein
when the first epitaxial semiconductor layer includes the silicon carbide layer, n-type impurities are introduced into the silicon carbide layer, and n-type impurities are implanted into the semiconductor region by an ion implantation method.

10. The semiconductor device according to claim 1, further comprising a second epitaxial semiconductor layer formed between the first epitaxial semiconductor layer and the silicide film by the epitaxial growth method.

11. A semiconductor device comprising:
element isolation regions formed in a semiconductor substrate of a first conductivity type;
a gate insulator formed on the semiconductor substrate between the element isolation regions;
a gate electrode formed on the gate insulator;
sidewall insulating films formed on side surfaces of the gate electrode;
a first epitaxial semiconductor layer of a second conductivity type formed by the epitaxial growth method in each of trenches formed on the semiconductor substrate between the element isolation regions and the gate electrode, the first epitaxial semiconductor layer having a facet;
a second epitaxial semiconductor layer formed on the first epitaxial semiconductor layer by an epitaxial growth method; and
a silicide film formed on the second epitaxial semiconductor layer.

12. The semiconductor device according to claim 11, wherein
the first epitaxial semiconductor layers are formed in such a manner that a part of the semiconductor substrate under the gate electrode is interposed between the first epitaxial semiconductor layers, and constitute a source region and a drain region.

13. The semiconductor device according to claim 11, wherein
the facet is formed on a part of the first epitaxial semiconductor layer on the element isolation region side.

14. The semiconductor device according to claim 11, wherein
the first epitaxial semiconductor layer includes any one of a silicon germanium layer and a silicon carbide layer.

15. The semiconductor device according to claim 14, wherein
when the first epitaxial semiconductor layer includes the silicon germanium layer, p-type impurities are introduced into the silicon germanium layer.

16. The semiconductor device according to claim 14, wherein
when the first epitaxial semiconductor layer includes the silicon carbide layer, n-type impurities are introduced into the silicon carbide layer.

17. A method of manufacturing a semiconductor device comprising:
forming element isolation regions in a semiconductor substrate of a first conductivity type;
forming a gate insulator on the semiconductor substrate between the element isolation regions;
forming a gate electrode on the gate insulator;
forming sidewall insulating films on side surfaces of the gate electrode;
forming trenches on the semiconductor substrate between the element isolation regions and the gate electrode;
introducing impurities of a second conductivity type into the semiconductor substrate under each of the trenches by ion implantation to form a semiconductor region of the second conductivity type;
forming a first epitaxial semiconductor layer of the second conductivity type in each of the trenches, the first epitaxial semiconductor layer having a facet; and
forming a silicide film on the first epitaxial semiconductor layer.

18. The method of manufacturing a semiconductor device according to claim 17, wherein
the impurities are not introduced into a part of the semiconductor substrate under each sidewall insulating film by the ion implantation for forming the semiconductor region.

19. The method of manufacturing a semiconductor device according to claim 17, wherein
the semiconductor region is arranged between the semiconductor substrate of the first conductivity type and the first epitaxial semiconductor layer.

20. The method of manufacturing a semiconductor device according to claim 17, wherein
the facet is formed on a part of the first epitaxial semiconductor layer on the element isolation region side.
